(19) United States
(12) Patent Application Publication
(10) Pub. No.: US 2006/0216966 A1
(43) Pub. Date: Sep. 28, 2006

(54) Distribution Vehicle

(76) Inventor: Ali Saban Selek, Istanbul (TR)

Correspondence Address: COLLEN IP, THE HOLYOKE MANHATTAN BUILDING, 80 SOUTH HIGHLAND AVENUE, OSSINING, NY, 10562, US

(21) Appl. No.: 10/907,230

(22) Filed: Mar. 24, 2005

(51) Int. Cl. H05K 1/00

(52) U.S. Cl. 439/76.2

(57) ABSTRACT

A distribution vehicle and method for improved means to efficiently load and deliver ordered products to a customer. The distribution vehicle includes the vehicle, a distribution box, and order boxes. The vehicle also includes a means to preserve perishable items during transport. This invention includes the methods to efficiently load order products into the order boxes and identify its exact location in the distribution box. The distribution box is loaded into the distribution vehicle after the order boxes filled with ordered products have been loaded into the distribution box.

### BACKGROUND

Existing distribution vehicles used for retailing distribution of goods typically

have the following characteristics:

loaded manually or by fork lifts,

one door in the back,

contents of vehicle are known but not exact location within the vehicle,

contents are grouped by product not by delivery point,

no racks, compartments, etc. in the body except for the ones designed

especially for distribution of specific products (ice cream, drinks, meat, etc.).

At every stop the delivery person locates and assembles the specific products and quantities of that stop.

### SUMMARY OF INVENTION

This invention relates to an order distribution vehicle and its components including vehicle, distribution box, order box and cold storage unit and methods for various applications in retail distribution of goods such as food, cleaning, health and care typically within a defined geographic area.

This invention has many excellent and completely different features from existing vehicles including improved means and methods for both loading and unloading, and the efficient use of every part of the distribution vehicle. The distribution box of this vehicle can even be applied for use in international deliveries.

Objectives of this invention include:

Efficient use of every part of order distribution vehicle, thus maximizing possible transportation in terms of volume,

Providing the quickest loading of the orders into the distribution vehicle, in order to minimize the idle time of the distribution vehicle and vehicle staff during loading.

Minimizing spoiling of perishable orders during transportation, especially in certain climates due to the reduced time of transportation,

Faster delivery of the orders at the distribution points,

Minimizing complexities in the stages of both loading and unloading,

Identifying the location of the orders in the distribution vehicle, in order to reach the order package easily and quickly at the time of delivery.

### BRIEF DISCRIPTION OF DRAWINGS

In order to describe the order distribution vehicle and its elements developed with this invention, figures are prepared and attached including.

FIG. 1 is a front right perspective view of the distribution vehicle with distribution box.

FIG. 2 is a front right perspective view of the distribution vehicle without distribution box.

FIG. 3 is a front right perspective view of the distribution box.

FIG. 4 is a front right perspective view of the order box.

FIG. 5 is a front right perspective view of the cold storage unit.

FIG. 6 depicts a distribution box ready to load into the distribution vehicle.

FIG. 7 is a rear lower perspective view of a distribution box.

FIG. 8 depicts a distribution box being loaded into the top of the vehicle.

FIG. 9 depicts loading multiple order boxes into distribution box.

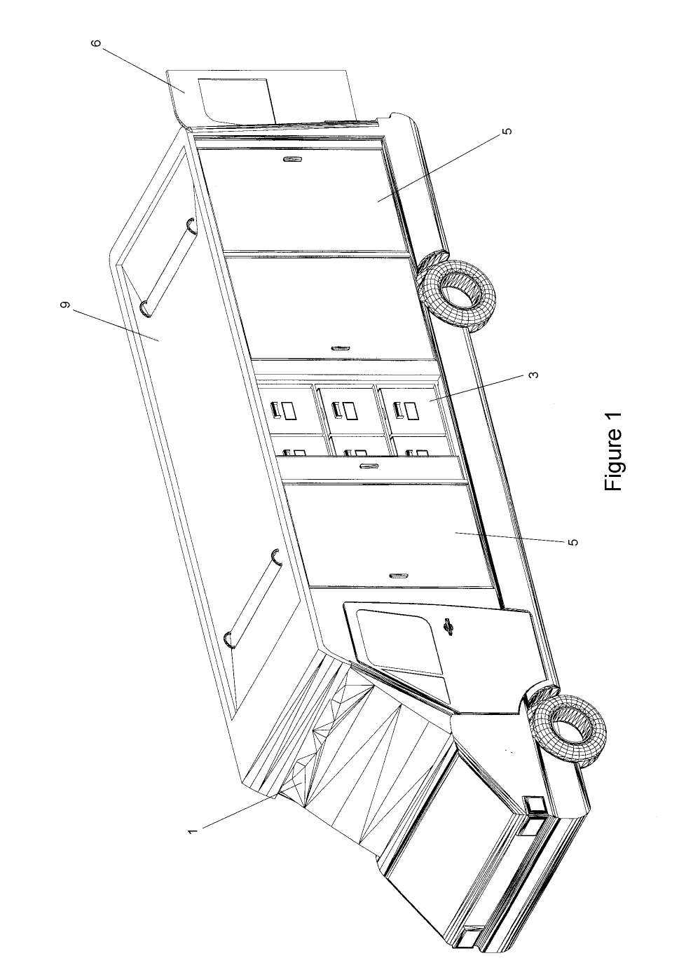

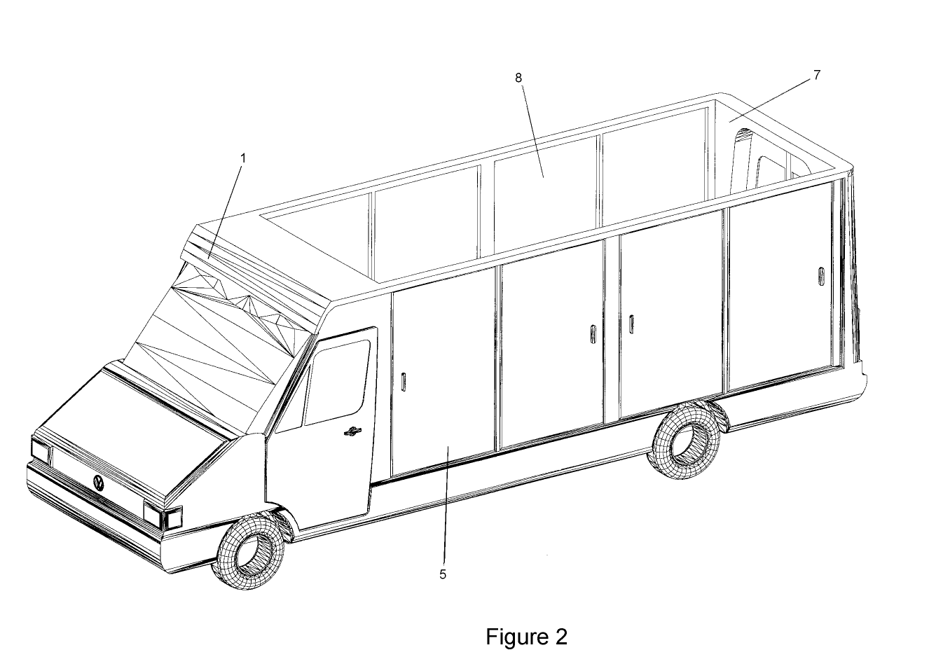

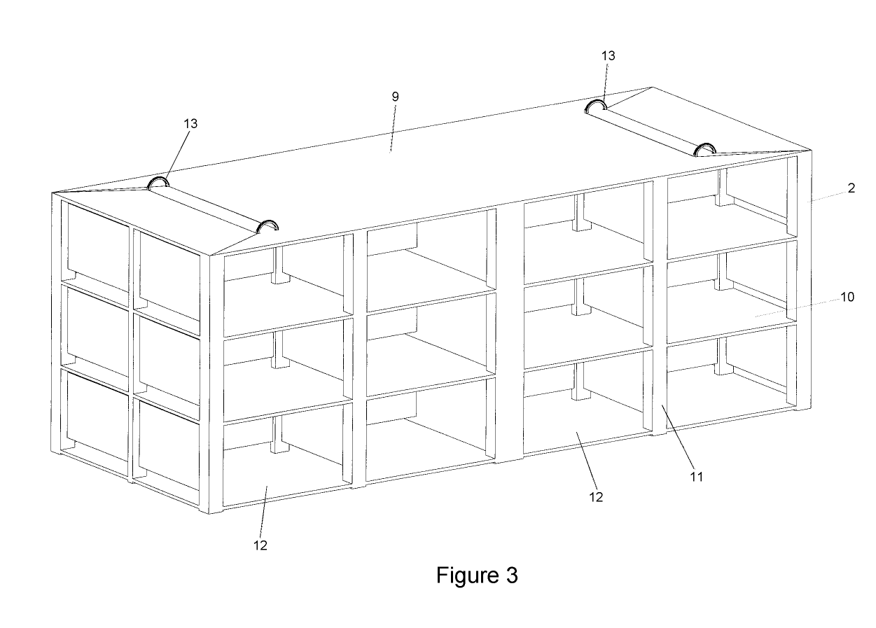

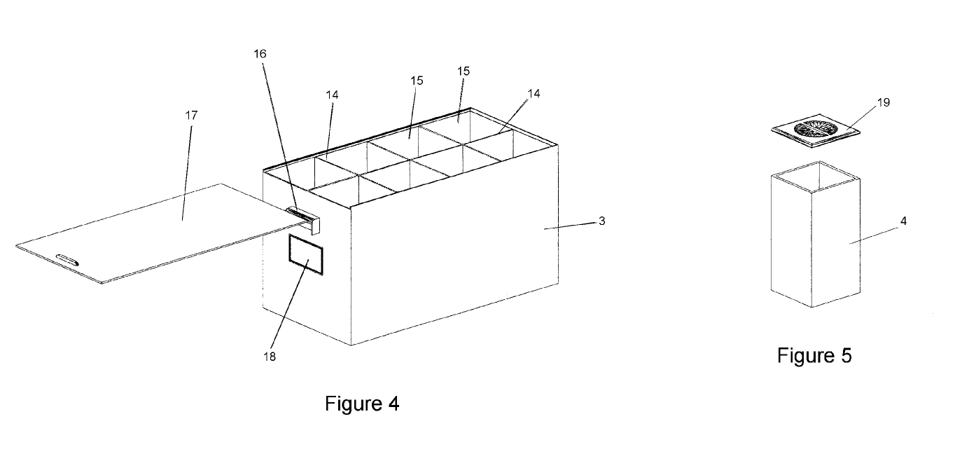

Parts in the above-mentioned figures are numbered separately in order to clearly identify each. Each numbered part's description is as follows.

(1) Distribution vehicle

(2) Distribution box

(3) Order box

(4) Cold storage unit

(5) Side doors

(6) Rear Door

(7) Top of distribution vehicle

(8) Cargo cabin

(9) Distribution box top

(10) Distribution box horizontal racks

(11) Distribution box vertical internal partition

(12) Distribution box compartments

(13) Crane hook slots

(14) Order box partitions

(15) Order box compartments

(16) Order box carrying holders

(17) Removable Order box cover

(18) Order box address sticker slot

(19) Cold storage unit cover

The main parts of the order distribution vehicle are the distribution vehicle (1), distribution box (2), order box (3) and cold storage unit (4).

The primary objectives of this invention of a distribution vehicle and its elements, are: to provide the maximum usage of every part of the distribution vehicle (1), especially cargo cabin (8) in terms of volume; to provide for the advance loading of the distribution box (2) like containers; to load the distribution box into the distribution vehicle (1) from the top, side or back; and to unload order boxes (3) from the sides or rear.

The distribution vehicle (1), preferably has an open-top (7) (or openable sides or back); a driver controls and seat in the front; doors (5 and 6) on the sides or back; and an open cargo cabin (8). This vehicle is preferably the size of a small cargo vehicle, small truck or minibus, midi bus or little lorry, but it can be designed to any size. A main feature of the vehicle is doors (5 and 6) at sides and back, in any number and shape required to provide easy access to each order box. The vehicle can be designed with a roof over the body of the cargo cabin or left open as required.

The distribution box (2) is a closed-top (9) box, consisting of multiple compartments with access to these compartments from two or three sides. The distribution box is designed to fit into the distribution vehicle (1) cargo cabin space (8). Horizontal racks (10) in the distribution box are installed in accordance with the order box (3) sizes. The racks (10) and vertical internal partitions (11) from the compartments (12). Order boxes (3) are placed in the order compartments in the distribution box (2). On the top (9) of the distribution box (2), there are an appropriate number of crane hook slots (13) or similar holding elements to provide for lifting with a crane. The top (9) of distribution box (2) can be designed to also be the top (7) (roof) of the vehicle cargo cabin (8). When the distribution box (2) is placed in the cabin (8), it fits completely in the cabin (8). It can be designed to prevent the entrance of water, air, dust, etc. into the cabin (8) and the distribution box.

The order box (3) is designed with a removable top which is typically closed by sliding a cover (17) into slots on the top walls of the order box. The order box is preferably closed except for the removable cover (17) and divided into compartments (15) by partitions (14). Dimensions and volumes of the order box compartments can be changed by adding, removing or relocating the partitions (14) to accommodate the size of the orders. Carrying holders (16) and address sticker slots (18) are included as desired on the side of order box (3).

A cold storage unit (4) is an insulated unit which is sized to fit in 1 or more compartments of an order box. It is closed except for the cover (19) which is insulated and removable. The cold storage unit can also be provided with refrigeration powered by the distribution vehicle.

Key features of this invention for a distribution vehicle and its elements:
(1) The distribution box (2) is separate from the distribution vehicle (1) but designed to be placed in the distribution cabin (8).
(2) Contrary to classic distribution vehicles, this distribution vehicle can be loaded in one step typically from the top while unloading is typically done from side doors (or rear door if designed to allow such).
(3) Products or product groups are placed in order box compartment (15) in an order box (3). Perishable at risk of spoiling corruption during transportation are placed in cold storage units (4) if needed. Automated loading of the order boxes is also possible utilizing a computer based system.
(4) Each distribution box compartment and each order box compartment is identified with the address for its delivery.
(5) After a distribution vehicle has completed its deliveries, the empty distribution box can be removed. Another distribution box (2) which is filled with products to be distributed can be immediately loaded into the distribution vehicle's (1) cabin (8). In this way, the distribution vehicle (1) and delivery personnel spend minimal time in the loading effort.
(6) If the loading has been done in accordance with delivery addresses, the delivery personnel know which specific door of the distribution vehicle (1)'s cabin (8) to open at each delivery site. This minimizes the time required at each delivery site and ensures the correct products are delivered.
(7) A distribution box (2) is divided into compartments (12) which are sized to accept appropriately sized order boxes (3). The order boxes are individually organized and identified to support convenient access at each delivery site. The specific order box (3) intended to be delivered at a particular is readily identified by the delivery personnel.
(8) The top (8) of the distribution box (2) may be designed to be the top of the distribution vehicle and prevent entry of water, dust, etc.
(9) The distribution vehicle, distribution box and order boxes are each designed to transport any standard or non-standard sized product packages and maximize the use of all available space in each.

A preferred embodiment of this invention for a distribution vehicle and its elements is explained below.

An order box (3) is a box preferably 45×85×45 cm, weighing not more than 20 kilograms when filled, containing variably sized compartments (15) and specially designed for this application.

There are three rows of racks (10) on each side of distribution box (2). Each row is divided into four vertical internal partitions to form 12 compartments (12) (11). Two order boxes (3) are placed next to each other in each compartment (12) in the distribution box (2).

The distribution box is thus designed to accept 24 order boxes from each side of the truck. To facilitate local distribution, the distribution vehicle (1) is designed to enter the narrow streets in a city; and is preferably not bigger than a minibus in terms of size.

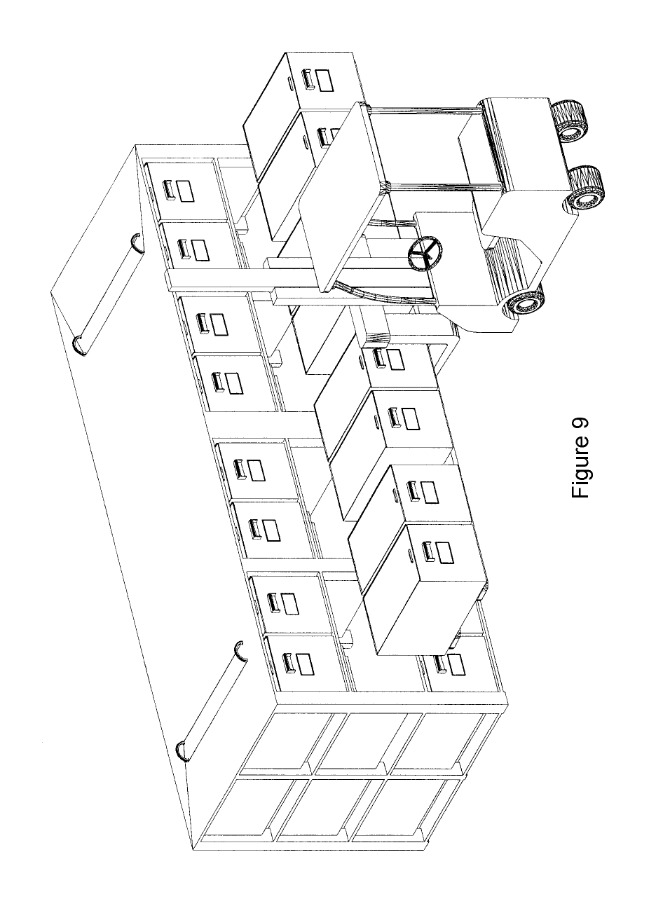

Order boxes (3) are loaded into distribution boxes (2) in a specially designed logistic warehouse. Loading is done preferably with fork lifts designed for this work in which 24 order boxes can be loaded together into one side of a distribution box (2) or loaded in three groups of eight as shown in FIG. 9. Loading is done based on the delivery plan for that vehicle which is typically established and controlled by a computer. The loading is designed to efficiently support the delivery plan for a particular delivery. The plan is given to the distribution staff to ensure they know exactly where each order box (3) is located, where it is to be delivered, and the route to be followed. In this way, at the stage of delivery, distribution staff would be able to find and deliver the order easily, without confronting any problems.

The distribution vehicle (1) has doors on its sides consistent with the locations of the distribution box compartments (12). It has an open top (7) and empty cabin space (8). The distribution box is loaded into the cargo order (8) from the top. The upper part of the distribution box (2) covers the open roof of the distribution vehicle (1) and acts as the roof of the distribution vehicle (1). It prevents entry air, water, dust etc., and completes the aerodynamic design of the vehicle. There are preferably 4 doors (5) on each side of distribution vehicles (1). Each door preferably sliding to the side, to provide access to reach the 6 order boxes in one part of the distribution box. The sliding doors can be automated.

A distribution box (2) loaded with order boxes (3) is loaded into a distribution vehicle (1) with a crane. For this purpose, a distribution vehicle (1) enters a loading platform. An empty distribution box (2) is removed from the vehicle (1) with a crane. A loaded distribution box (2) is then placed in the cabin (8) with a crane.

The entire loading process for the vehicle is performed at the designed platforms. As the distribution vehicle (1) enters the warehouse it first stops at the designated unloading point. The crane system removes the empty distribution box (2) from the distribution vehicle (1). The distribution vehicle (1) then moves to the designated loading point. The crane system places a loaded distribution box (2) into the distribution vehicle's cabin (8). Vehicle staff do not need to leave their vehicles or perform any operation during the unloading and loading process which is predicted to last not more than 3 minutes. This maximizes the efficiency by minimizing the idle time of distribution staff and distribution vehicle (1) during unloading and loading process.

After the completion of loading, a delivery plan is given to the vehicle staff, showing which order box (3) is in each location in the distribution box (2) and identifies the address (customer) for delivery of each order box (3). The plan also identifies the route the vehicle is to follow. This information can also be transferred to the vehicle computer using a wireless system (for instance with Bluetooth-GPRS technology).

The entire process of loading the order boxes, loading the distribution box, loading the distribution vehicle and the development of the particular delivery plan can be fully or partially implemented by a computer-based system.

At each delivery point, the staff review the list to identify the order box(es)(3) to be delivered to that address and its location in the distribution box (3). They will quickly know exactly which door to use to access to the order box (3) and can immediately remove the correct order box.

The doors are designed to be locked. In designing the distribution vehicle (1), a mechanism can be included to enable opening each door separately from the driver's seat. Staff opens the lock of the related door before getting out of the vehicle, and closes the door after getting the order box(es) (3) to be distributed. When the door is closed, an automatic lock will eliminate the thefts.

In the preferred embodiment, the distribution vehicle (1) is designed to enable easy access to any order box for individuals of normal height and strength. When there is a delivery of more than one order box to the same address/customer, staff can use a handcart to carry order boxes. Handcarts carriers can be stored in special compartments such as under the doors on both sides of the vehicle (1), or placed inside of the back door.

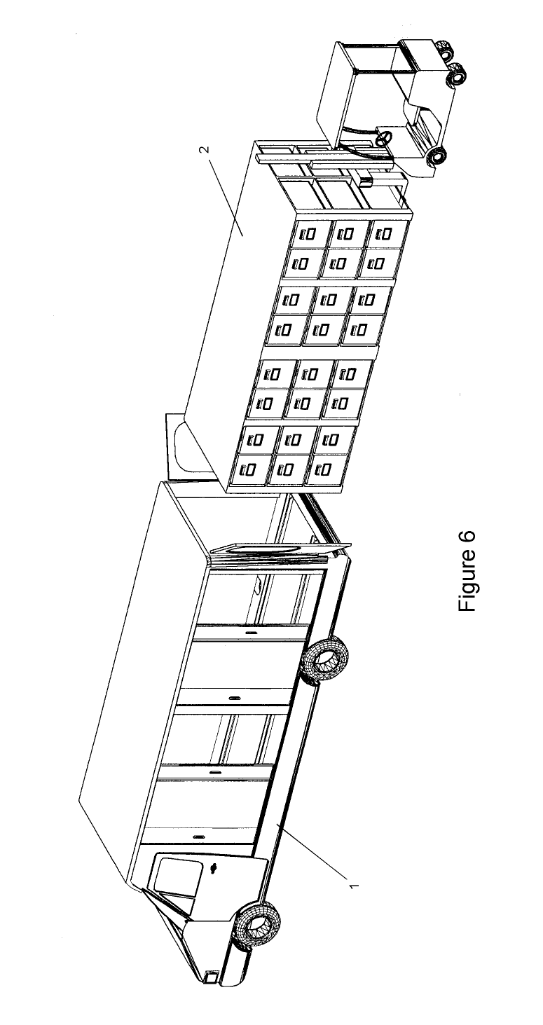

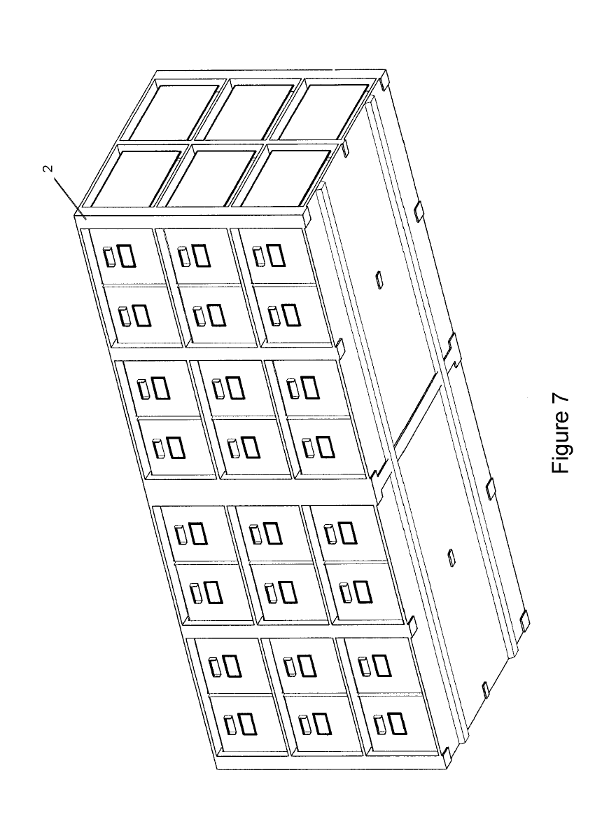

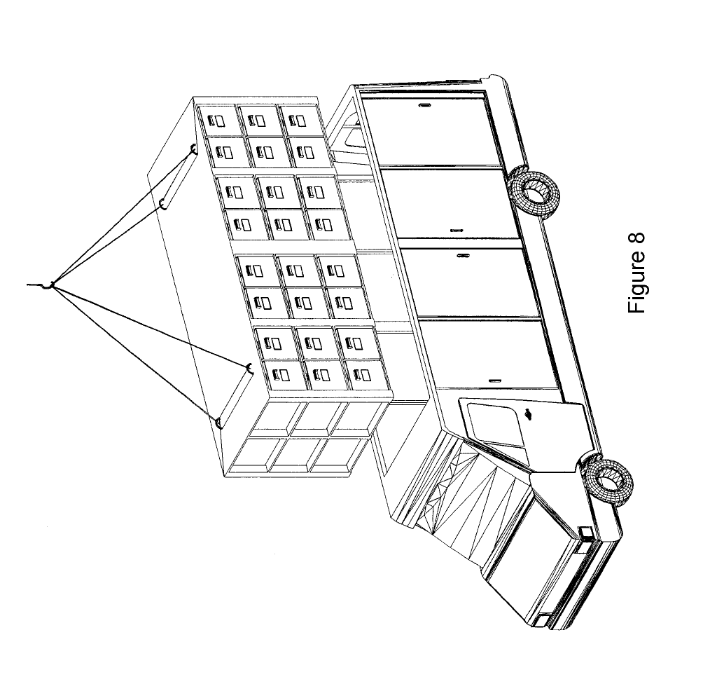

In other embodiments of this invention, the vehicle can also have door(s) at the rear. These doors can be designed to allow loading of the distribution box (3) from the rear (as shown in FIG. 6). Rear door(s) can also provide access to the order boxes if the distribution box is also designed to allow such.

A door(s) can also be designed to provide access to an open area of the distribution vehicle (1) beside the distribution box (2), for general purpose use. This area can be used to carry large-sized orders which don't fit in an order box (3).

This invention includes a method designed to maximize the efficiency available by use of this vehicle. It is intended that the distribution vehicle will typically be loaded in a warehouse intended to utilize this distribution vehicle with a loading process defined to load the order boxes as required for particular deliveries. The process will typically be controlled by a computer based order system with personnel required minimized.

The description above and accompanying figures are presented as examples of the present invention. The scope of the present invention is not limited by the exemplary embodiments. Other applications and variations of the present invention are possible to meet a particular application. For example, the distribution box could be essentially permanently mounted in the vehicle and the order boxes loaded directly into the truck. It is recognized that departures from the disclosed embodiments may be made within the scope of the invention and that obvious modifications will occur to a person skilled in the art. Those of skill in the art should, in light of the present disclosure, appreciate that many changes can be made in the specific embodiments which are disclosed herein and still obtain a like or similar result without departing from the spirit and scope of the invention. All of the embodiments disclosed and claimed herein can be made and executed without undue experimentation in light of the present disclosure.

What is claimed is:

1. A distribution vehicle comprising:
A vehicle capable of being driven;
An open cargo area in the vehicle;
A distribution box designed to fit into the cargo area;
Order boxes located in compartments in the distribution box and;
Doors in the vehicle to allow access to each order box.

2. A distribution vehicle according to claim 1, in which the compartments in the distribution box are created by horizontal racks and vertical partitions which are installed to be compatible with at least one order box to be housed.

3. A distribution vehicle according to claim 2 in which the order box has a front and rear, 2 sides, a top, bottom and is divided into compartments by movable and removable partitions to create the dimensions and volume required by product(s) to be delivered.

4. A distribution vehicle according to claim 3 in which the top of the order box is designed to allow access.

5. A distribution vehicle according to claim 3 in which carrying holders and addresses sticker slots are provided on the order box as required.

6. A distribution vehicle according to claim 3 in which the order box includes to includes at least one cold storage unit which is insulated and closed on all sides with a removable opening for access.

7. A distribution vehicle according to claim 3 in which the order box is typically 45×85×45 cm and weighing not more than 20 kilograms including its contents.

8. A distribution vehicle according to claim 2 in which the distribution box has a front, rear, 2 sides, a top and a bottom and is typically divided into 3 rows of 4 compartments on each of the two sides.

9. A distribution vehicle according to claim 8 in which the distribution vehicle typically has 4 doors on each side of the vehicle.

10. A distribution vehicle according to claim 2 in which doors are provided and located on the sides and rear of the distribution vehicle as required to provide access to each order box.

11. A distribution vehicle according to claim 10 in which the doors are of a sliding design.

12. A distribution vehicle according to claim 10 in which the doors can be locked and unlocked from inside the distribution vehicle with a provision to allow automatic locking when a door is closed.

13. A distribution vehicle according to claim 1, in which the top of the cargo area is open to allow the loading of the distribution box into the cargo area of the vehicle through its open top; and the distribution box being designed for exposure to the environment and to prevent the entrance of water, air and particles.

14. A distribution vehicle according to claim 13 in which the distribution box is provided with crane hook attachment devices for lifting.

15. A distribution vehicle according to claim 1 in which the distribution box is loaded into the distribution vehicle from the rear of the vehicle.

16. A distribution vehicle according to claim 1 in which the distribution box can be loaded into the distribution vehicle from at least one side.

17. A distribution vehicle according to claim 1 in which open space is provided in the distribution vehicle separate from the distribution box and accessible by at least one door of the distribution vehicle.

18. A distribution vehicle according to claim 1 in which the loading of the order boxes, distribution box and distribution vehicle is controlled by a computer system.

19. A distribution vehicle comprising:
A vehicle capable of being driven;
An open cargo area in the vehicle;
A distribution box designed to fit into the cargo area;
A means to load the distribution box into the cargo area;
A means to divide the distribution box into compartments;
An order box designed to fit into a compartment in the distribution box;
A means to load order boxes into the compartment in the distribution box;
A means to allow access by delivery personnel to the order boxes without removal of the distribution box;
A means to divide the order box into compartments.

20. A distribution vehicle according to claim 19 further comprising a means to lock and unlock the access door (s) from inside the distribution vehicle.

21. A distribution vehicle according to claim 19 further comprising a means to maintain perishable orders at a required temperature.

22. A distribution vehicle according to claim 19 in which the distribution box is designed to be exposed to the environment and prevent the entrance of water, air and particles.

23. A distribution vehicle according to claim 19 further comprising a means to load the order boxes, distribution box and distribution vehicle using a computer controlled system.

24. A distribution vehicle according to claim 19 further comprising a means to identify each order box for delivery to a specified location and customer.

25. A method to deliver product(s) to a customer comprising:
Creating a distribution vehicle capable of being driven;
Creating a distribution box of an appropriate size to fit into a cargo area of the distribution vehicle;
Dividing the distribution box into compartments designed to house at lease one removable order box in each compartment;
Dividing the order box into compartments designed to house product(s) for delivery;
Identifying a particular customer and location of delivery for each order box;
Filling each order box with the product(s) ordered by the particular customer;
Loading the order box into the distribution box;
Loading the distribution box into the distribution vehicle;
Driving the vehicle to a particular customer location;
Removing the identified order box(es) for a particular customer location; and delivering the ordered product(s) to the customer.

26. A method according to claim 25 further comprising loading the distribution box with filled order boxes into the distribution vehicle through an open top in the distribution vehicle.

27. A method according to claim 25 further comprising loading the distribution box with filled order boxes into the distribution vehicle through a door opening in one side of the distribution vehicle.

28. A method according to claim 25 further comprising a means to maintain perishable orders at a required temperature.

29. A method according to claim 25 further comprising a means to lock and unlock the access door (s) from inside the distribution vehicle.

30. A method according to claim 25 further comprising loading the order boxes in as part of a computer controlled process.
